(19) United States
(12) Patent Application Publication
(10) Pub. No.: US 2024/0387500 A1
(43) Pub. Date: Nov. 21, 2024

(54) MULTI-CHIP PACKAGE AND METHOD OF MAKING

(71) Applicant: Yibu Semiconductor Co., Ltd., Shanghai (CN)

(72) Inventor: Ming Li, Fremont, CA (US)

(73) Assignee: Yibu Semiconductor Co., Ltd., Shanghai (CN)

(21) Appl. No.: 18/664,273

(22) Filed: May 14, 2024

(30) Foreign Application Priority Data
May 15, 2023 (CN) 202310545775.6

(51) Int. Cl. H01L 25/00; H01L 21/56; H01L 23/00; H01L 23/31; H01L 25/065

(52) U.S. Cl. CPC H01L 25/50; H01L 21/568; H01L 23/3185; H01L 24/11; H01L 24/13; H01L 24/16; H01L 24/19; H01L 24/20; H01L 24/81; H01L 24/95; H01L 25/0652; H01L 25/0655; H01L 2224/11003; H01L 2224/111; H01L 2224/11334; H01L 2224/13082; H01L 2224/13124; H01L 2224/13139; H01L 2224/13144; H01L 2224/13147; H01L 2224/13186; H01L 2224/16145; H01L 2224/16225; H01L 2224/19; H01L 2224/214; H01L 2224/81005; H01L 2224/95001; H01L 2924/0549

(57) ABSTRACT

The present disclosure relates to a multi-chip package and a method of manufacturing the same. The method comprises providing a first support carrier, and forming first conductive bumps and an interconnection device on a surface on one side of the first support carrier. The interconnection device has a passive side attached to the first support carrier and an opposing active side provided with second conductive bumps. The method further comprises connecting an active side of each chip of at least two chips to a respective subset of the first conductive bumps and a respective subset of the second conductive bumps. Thus, the chips can be electrically connected to an external device through the first conductive bumps, and electrically connected to each other through the second conductive bumps, without an interposer layer or Through-Silicon Vias (TSV), thereby reducing the manufacturing cost and simplifying the chip package integration process.

### CROSS REFERENCE TO RELATED APPLICATION

This application claims the benefit of priority under the Paris Convention to Chinese Patent Application No. 202310545775.6A, filed on May 15, 2023, which is incorporated herein by reference in its entirety.

### TECHNICAL Field

The disclosure relates to the technical field of semiconductors, and in particular to a multi-chip package and a method of making a multi-chip package.

### BACKGROUND

With the development of integrated circuit technology, 2.5D and 3D System in Package (SiP) technologies are becoming increasingly mature, and multiple chips can be integrated in a package. Among related technologies, a chip is generally placed on top of an interposer having Through-Silicon Vias (TSV), and the chip is connected to the Through-Silicon Vias (TSV) through a redistribution layer. The interposer layer is made of silicon and organic materials, and an upper layer and a lower layer of the interposer are connected through TSVs. However, the area of an interposer is generally large, and the process of fabricating TSVs is relatively complex, resulting in increased cost.

### SUMMARY

To solve or alleviate the above technical problems, the present disclosure provides a chip package and a method for manufacturing the same.

In the first aspect, the present disclosure provides a method for manufacturing a chip package, including the following processing steps.

A first support carrier is provided, and first conductive bumps and an interconnection device are formed on one side of the first support carrier; wherein the interconnection device has opposing active side and passive side, the passive side of the interconnection device is attached to the first support carrier, and the active side of the interconnection device has second conductive bumps.

At least two chips are provided, each chip having an active side and a passive side, and the active side of each chip is connected to a respective subset of the first conductive bumps and a respective subset of the second conductive bumps.

In some embodiments, forming first conductive bumps and an interconnection device on a surface on one side of the first supporting carrier includes:

Forming a seed layer on a surface on one side of the first support carrier;

Forming a photoresist layer with a through hole pattern on the surface of one side of the seed layer that is facing away from the first support carrier; wherein the through hole pattern includes through holes penetrating the photoresist layer;

Forming the first conductive bumps in the through holes; and

Removing the photoresist layer.

An interconnection device with second conductive bumps is provided and the passive side of the interconnection device is attached to a surface on a side of the seed layer that is facing away from the first support carrier.

In some embodiments, forming of first conductive bumps and an interconnection device on a surface on a side of the first supporting carrier includes:

Attaching the passive side of the interconnection device to a surface on a side of the first support carrier; and

Forming a seed layer on the surface of the first support carrier which is facing the interconnection device; wherein the seed layer covers a surface on a side of the first support carrier which is facing the interconnection device, an active side of the interconnection device, and a peripheral surface of the interconnection device.

First conductive bumps are formed on the surface of the seed layer that is facing away from the first support carrier, and second conductive bumps are formed on the surface of the seed layer that is facing away from the interconnection device.

In some embodiments, before the active side of each chip is connected to the first conductive bumps and the second conductive bumps, the method further includes:

Removing the seed layer.

In some embodiments, before the active side of each chip is connected to the first conductive bumps and the second conductive bumps, the preparation method further includes the following processing steps.

The second support carrier is provided, and the passive sides of the at least two chips are attached to a surface on one side of the second support carrier.

In some embodiments, the preparation method further includes:

Forming a molded packaging layer between the first support carrier and the second support carrier; wherein the molded packaging layer embeds the interconnection device, the first conductive bumps, the second conductive bumps, and the chips.

In some embodiments, the preparation method further includes:

Form third conductive bumps on the side of the first conductive bumps that is facing away from the chip; the third conductive bumps are connected with the first conductive bumps, and the third conductive bumps are used for connecting with an external device.

In some embodiments, before forming the third conductive bumps on the side of the first conductive bumps that is facing away from the chip, the preparation method further includes:

Form a redistribution layer on the side of the first conductive bumps that is facing away from the chip; the redistribution layer is located between the first conductive bumps and the third conductive bumps, and the first conductive bumps are connected with the third conductive bumps through the redistribution layer.

In the second aspect, the present disclosure further provides a chip package prepared by any one of the above preparation methods; the chip package includes: first conductive bumps, an interconnection device, and at least two chips.

An interconnection device has active and passive sides, the active side of the interconnection device including second conductive bumps; the active side of each chip is connected to a respective subset of the first conductive bumps and a respective subset of the second conductive bumps.

In some embodiments, the chip package further includes: a molded packaging layer.

The molded packaging layer embeds the interconnection device, the first conductive bumps, the second conductive bumps, and the chip; the first conductive bumps are exposed at one side of the molded packaging layer that is facing away from the chip.

Compared with prior technologies, the technical scheme provided by the disclosure has the following advantages.

The chip package and the preparation method provided by the disclosure include: providing a first support carrier, forming first conductive bumps and an interconnection device on a surface on one side of the first support carrier; the interconnection device has opposing active side and passive side, the passive side of the interconnection device is attached to the first support carrier, and the active side of the interconnection device comprises second conductive bumps; at least two chips are provided, and the active side of each chip is connected to a respective subset of the first conductive bumps and a respective subset of the second conductive bumps. Therefore, the first conductive bumps and the interconnection device with the second conductive bumps are formed on a surface on one side of the first support carrier,, the active side of each chip is connected with the first conductive bumps and the second conductive bumps respectively, the chips can be electrically connected with external devices through the first conductive bumps, and the chips can be electrically connected with each other through the second conductive bumps without an interposer layer and a through silicon via, thus the manufacturing cost is reduced, and meanwhile, the integrated packaging process of the chips is simplified.

### BRIEF DESCRIPTION OF THE DRAWINGS

The accompanying drawings, which are incorporated in and constitute a part of this specification, illustrate embodiments consistent with the disclosure and together with the description, serve to explain the principles of the disclosure.

In order to more clearly illustrate the embodiments of the present disclosure or the solutions in the prior technologies, the drawings that are required for the description of the embodiments or the prior technologies will be briefly described below, and it will be obvious to those skilled in the technologies that other drawings can be obtained from these drawings without efforts.

FIG. 1 is a schematic flowchart of a method for manufacturing a chip package according to an embodiment of the disclosure.

FIG. 2 is a detailed flowchart of S110 in the chip package manufacturing method shown in FIG. 1.

FIG. 3 is another detailed flowchart of S110 in the chip package manufacturing method shown in FIG. 1.

FIGS. 4 to 17 are schematic structural diagrams corresponding to main process steps in the method for manufacturing a chip package according to the embodiments of the present disclosure.

### DETAILED DESCRIPTION OF THE EMBODIMENTS

In order that the above objects, features and advantages of the present disclosure can be more clearly understood, a further description of aspects of the present disclosure will be provided below. It should be noted that, without conflict, the embodiments of the present disclosure and features in the embodiments can be combined with each other.

In the following description, numerous specific details are set forth in order to provide a thorough understanding of the present disclosure, but the present disclosure can be implemented in other ways different from those described here; it will be obvious that the embodiments in the specification are only some, but not all, embodiments of the disclosure.

In order to solve the technical problems set forth in the background section, embodiments of the present disclosure provide a chip package and a method for manufacturing the same, where the method for manufacturing the chip package includes: providing a first support carrier, and forming first conductive bumps and an interconnection device on a surface on one side of the first support carrier; the interconnection device has opposing active side and passive side, the passive side of the interconnection device is attached to the first support carrier, and the active side of the interconnection device comprises second conductive bumps; at least two chips are provided, and the active side of each chip is connected to the first conductive bumps and the second conductive bumps respectively. Therefore, after the first conductive bumps and the interconnection devices with the second conductive bumps are formed on the surface of one side of the first support carrier, the active side of each chip is connected to the first conductive bumps and the second conductive bumps respectively, the chips can be electrically connected to external devices through the first conductive bumps, and the chips can be electrically connected to each other through the second conductive bumps without an interposer layer and a through silicon via, thus the manufacturing cost is reduced, and meanwhile, the chip package integration process is simplified.

The chip package and the manufacturing method according to the embodiments of the present disclosure will be exemplarily described below with reference to the accompanying drawings.

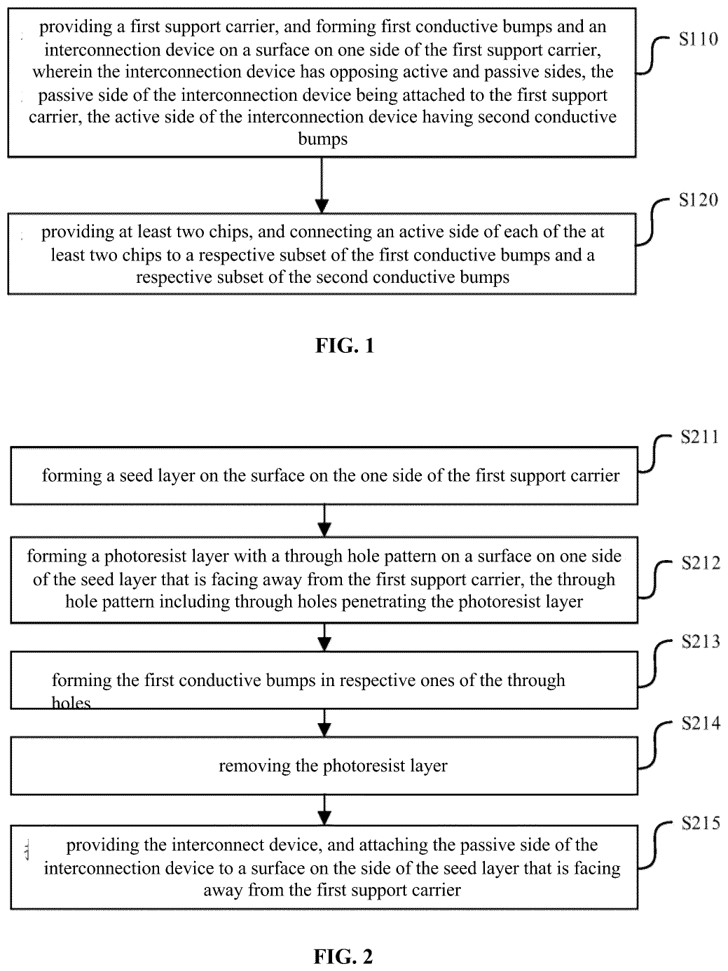

Exemplary, as shown in FIG. 1, it is a schematic flowchart of a method for manufacturing a chip package according to an embodiment of the present disclosure. Referring to FIG. 1, the preparation method includes:

S110, provide a first support carrier, and form first conductive bumps and an interconnection device on a surface on one side of the first support carrier; the interconnection device is provided with opposing active side and passive side, the passive side of the interconnection device is attached to the first support carrier, and the active side of the interconnection device comprises second conductive bumps.

The first supporting carrier is a temporary carrier and is used to prepare the first conductive bumps, to fix the interconnection devices, and to provide supporting functions for the first conductive bumps and the interconnection devices; as shown in FIGS. 6 and 14, the interconnection device 4 and the first conductive bumps 3 are located on the same surface on the one side of the first support carrier 1.

The first conductive bumps are prepared by electroplating or deposition process and is made of metal material and/or nonmetal material with good electrical conductivity, including at least one of copper, aluminum, silver, gold, titanium and indium tin oxide.

The active side and the passive side of the interconnection device are opposite to each other, the passive side of the interconnection device can be attached to a surface on one side of the first support carrier by using an adhesive or a sticky attachment film, the active side of the interconnection device is provided with a plurality of second conductive bumps, and the second conductive bumps are made of one or more conductive materials such as copper, aluminum, silver, gold, titanium, indium tin oxide and the like. The interconnection device is illustratively a silicon bridge chip or a chip with metal interconnecting wires.

As shown in FIGS. 6 and 14, the height of the first conductive bumps 3 are greater than the height of the second conductive bumps 43, and the thickness of the interconnection device 4 is consistent with the difference in height between the first conductive bumps 3 and the second conductive bumps 43, i.e., the height of the first conductive bumps are equal to the sum of the thickness of the interconnection device 4 and the height of the second conductive bumps, thus the ends of the first conductive bumps 3 and the second conductive bumps 43 connected to the chip 6 are kept flush; the first conductive bumps 3 and the second conductive bumps 43 can be shaped as bumps, and can also be shaped as pillars, which are not limited herein.

It should be noted that, in the embodiment of the present disclosure, the order of forming the second conductive bumps and the interconnection device on the surface of one side of the first support carrier is not limited, and the first conductive bumps and the interconnection device can be formed first, or the first conductive bumps and the interconnection device can be formed first and then.

S120, providing at least two chips, and connecting the active side of each chip to the first conductive bumps and the second conductive bumps respectively.

In some embodiments, the chips include all types of chips known to those skilled in the technologies, such as a memory chip, a computing chip, a communication chip, a sensing chip, and a power chip, which are not limited herein.

In some embodiments, connection points for electric connection are arranged on the active side of the chip; illustratively, the connection points are pads, which can be directly connected to the first conductive bumps and the second conductive bumps without forming a bumps.

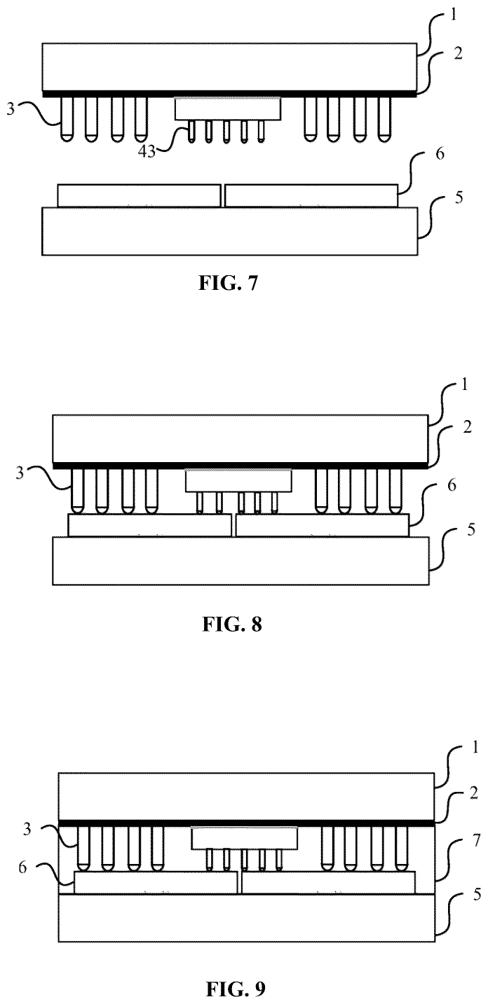

As shown in FIGS. 7 & 8 or FIGS. 15 & 16, an active side of the chip 6 is directed to the first conductive bumps 3 and the second conductive bumps 43, a portion of the connection points (not shown in the figure) of each chip 6 is connected to the first conductive bumps 3, the remaining portion of the connection points is connected to a portion of the second conductive bumps 43 of the interconnection device 4, and the remaining portion of the second conductive bumps 43 are connected to a portion of the connection points of the other chip 6. In other words, the interconnection device 4 is bridged between the two chips 6, a part of the second conductive bumps 43 of the interconnection device 4 are connected to one chip 6, and the remaining part of the second conductive bumps 43 are connected to the other chip 6, thus the two chips 6 are electrically connected through the interconnection device 4 and the second conductive bumps 43; the connection points of the remaining parts of the two chips 6 are connected to the first conductive bumps 3, thus the chips 6 can be electrically connected to external devices through the first conductive bumps 3.

The preparation method of the chip package provided by the embodiment of the disclosure comprises the following steps: provide a first support carrier, and form first conductive bumps and an interconnection device on a surface on one side of the first support carrier; the interconnection device has opposing active side and passive side, the passive side of the interconnection device is attached to the first support carrier, and the active side of the interconnection device comprises second conductive bumps; at least two chips are provided, and the active side of each chip is connected to the first conductive bumps and the second conductive bumps respectively. Therefore, after the first conductive bumps and the interconnection devices with the second conductive bumps are formed on the surface of one side of the first support carrier, the active side of each chip is connected to the first conductive bumps and the second conductive bumps respectively, the chips can be electrically connected to external devices through the first conductive bumps, and the chips can be electrically connected with each other through the second conductive bumps without an interposer layer and a through silicon via, thus the manufacturing cost is reduced, and meanwhile, the chip package integration process is simplified.

In some embodiments, as shown in FIG. 2, a detailed flowchart of S110 is illustrated in the preparation method of the chip package as shown in FIG. 1. Referring to FIG. 2, “forming first conductive bumps and an interconnection device on a surface on one side of a first support carrier” includes:

S211, form a seed layer on a surface on one side of the first support carrier.

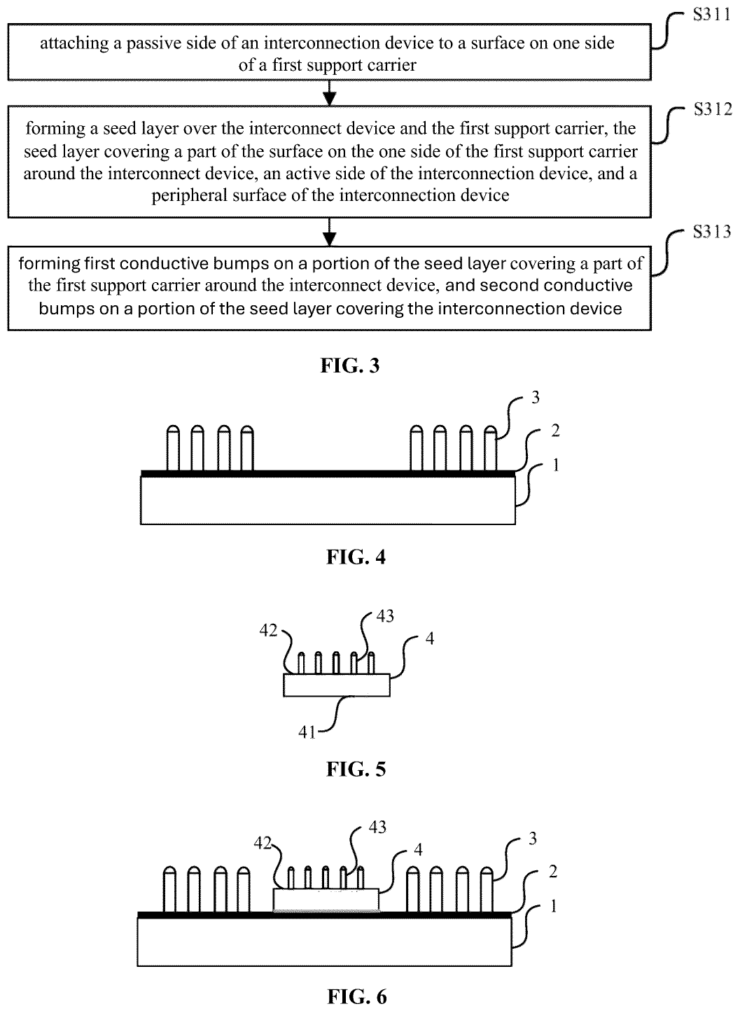

In the present embodiment, as shown in FIGS. 4 to 6, first, the second conductive bumps 3 are formed on a surface on one side of the first support carrier 1, and then the interconnection device 4 having the second conductive bumps 43 are attached; a seed layer is formed on the first support carrier before the first conductive bumps 3 are formed.

In some embodiments, the seed layer comprises at least one of copper and titanium.

S212, form a photoresist layer with a through hole pattern on the surface of one side of the seed layer that is facing away from the first support carrier.

In some embodiments, the through hole pattern includes holes penetrating the photoresist layer.

Specifically, a photoresist layer is deposited on a surface on the one side (i.e., an outward surface) of the seed layer that is facing away from the first support carrier, and then a mask layer is disposed on a surface on a side of the photoresist layer that is facing away from the seed layer, and after light irradiation, a patterned photoresist layer is formed, thus a through hole penetrating through the thickness of the photoresist layer is formed.

S213, form first conductive bumps in the through holes.

Specifically, the first conductive bumps are formed in the hole using electroplating, deposition, or other processes known to those skilled in the technologies.

S214, remove the photoresist layer.

After the photoresist layer is removed, the first conductive bumps 3 are located on a surface on a side of the seed layer 2 that is facing away from the first support carrier 1, as shown in FIG. 4.

In some embodiments, a cap bump is formed at an end of the first conductive bumps 3 that is facing away from the seed layer 2, and the bump is made of a conductive material, such as a solder material.

S215, providing an interconnection device with second conductive bumps and attaching a passive side of the interconnection device to a surface of a side of the seed layer that is facing away from the first support carrier.

In this embodiment, as shown in FIG. 5, the interconnection device 4 includes a passive side 41 and an active side 42 that are opposite to each other, and second conductive bumps 43 are provided on the active side 42. Illustratively, the second conductive bumps 43 are micro-bumps for the interconnection device 4.

Illustratively, as shown in FIG. 6, the passive side 41 of the interconnection device 4 is attached to the surface on one side of the seed layer 2 that is facing away from the first support carrier 1 with adhesive or a sticky attachment film; the interconnection device 4 and the first conductive bumps 3 are located on the same surface on the one side of the first support carrier 1.

In some embodiments, before connecting the active side of each chip with the first conductive bumps and the second conductive bumps, respectively, the method further includes:

A second support carrier is provided, with the passive sides of at least two chips attached to a surface on one side of the second support carrier.

For example, as shown in FIGS. 7-8, the passive side of the chips 6 can be attached to a surface on one side of the second support carrier 5 with adhesive or a sticky attachment film, the active side of the chips 6 that is facing away from the second support carrier, i.e. the active side of the chips 6 facing towards the first conductive bumps 3 and the second conductive bumps 43. The chips 6 are fixed on the second supporting carrier 5, thus the chips 6 are prevented from moving with respect to each other in the connecting process of the first conductive bumps 3 and the second conductive bumps 43, and the interconnect reliability is improved.

In some embodiments, after connecting the active side of each chip with respective first conductive bumps and second conductive bumps, the method further includes:

Forming a molded packaging layer or molding layer between the first support carrier and the second support carrier; the molded packaging layer or molding layer embeds the interconnection device, the first conductive bumps, the second conductive bumps and the chip.

The molded packaging layer or molding layer can use a prepreg to cover the surfaces of the interconnection device, the first conductive bumps, the second conductive bumps and the chips. In some embodiments, the prepreg comprises one or more of epoxy resin, polyethylene, polypropylene, polyolefin, polyamide, polyurethane and the like. The molded packaging layer or molding layer can also be made of liquid or powder epoxy resin and other materials, thus the surfaces of the interconnection device, the first conductive bumps, the second conductive bumps and the chip are covered, and gaps among the interconnection device, the first conductive bumps, the second conductive bumps and the chip are filled.

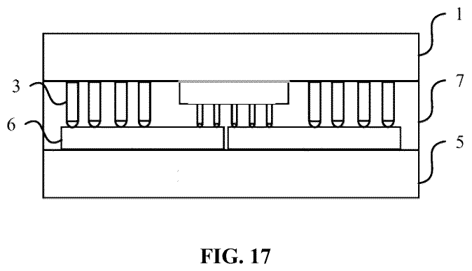

Illustratively, as shown in FIGS. 9 and 17, the molded packaging or molding layer 7 embeds the interconnection device, the first conductive bumps 3, the second conductive bumps 43, and the chip 6, and fills in the gaps between the interconnection device, the first conductive bumps 3, the second conductive bumps 43, and the chip 6.

In some embodiments, after forming the molding layer on a side of the first support carrier facing the interconnection device, the method further includes the following.

The first support carrier and the seed layer are removed to expose bottom surfaces of the first conductive bumps.

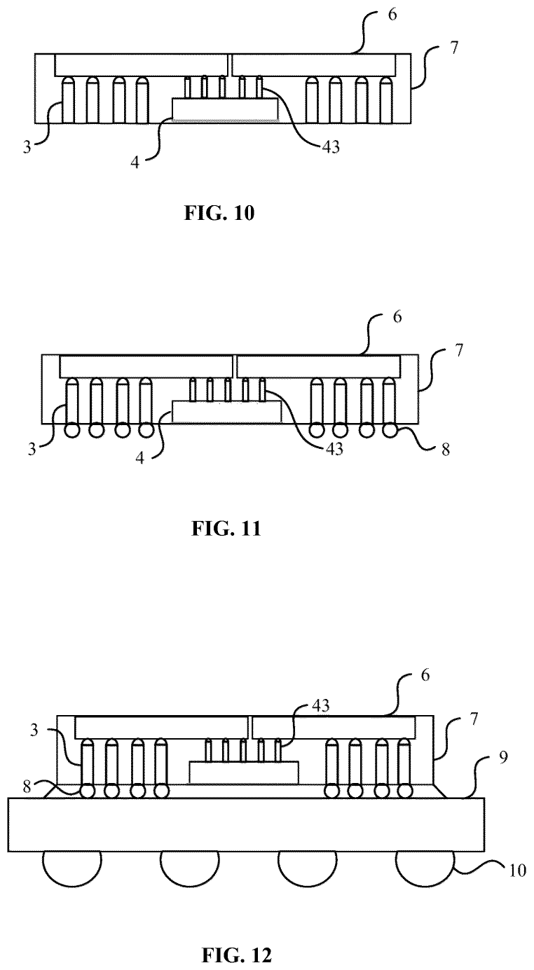

Illustratively, as shown in FIG. 10, after forming the molding layer 7, the first support carrier is removed, and the seed layer is removed by at least one of polishing, grinding and stripping processes until bottom surfaces of the first conductive bumps 3 are exposed at a surface on one side of the molding layer 7 that is further away from the chips 6.

In some embodiments, the method of making further includes:

Forming third conductive bumps on exposed bottom surfaces of the first conductive bumps that are facing away from the chips; the third conductive bumps are connected to the first conductive bumps, respectively, and the third conductive bumps are used for connecting to an external device.

The third conductive bumps can be configured as a column, a block, or a sphere, and the material of the third conductive bumps are an electrically conductive material including a metal material (such as at least one of copper, aluminum, silver, gold, tin and titanium) and an electrically conductive nonmetallic material. The number and arrangement of the third conductive bumps can be flexibly set according to external devices, which are not limited herein.

As illustrated in FIGS. 11-12, after the first support carrier 1 and the second support carrier 5 are removed, third conductive bumps 8 are formed on bottom surfaces of the first conductive bumps 3 that are facing away from the chips 6, and the first conductive bumps 3 are electrically connected to an external device 9 (e.g., a substrate) through respective ones of the third conductive bumps 8.

It should be noted that FIG. 12 only exemplarily illustrates that the external device is a substrate but the method for manufacturing the chip package provided in the embodiments of the present disclosure is not limited to the external device being a substrate. In other embodiments, the external device 9 can also be any device known to a person skilled in the technologies, such as a printed circuit board (PCB) or a processor, which can be a central processing unit (Central Processing Unit, CPU) or other form of processing unit having data processing and/or instruction execution capabilities.

In some embodiments, before forming the third conductive bumps on the bottom surfaces of the first conductive bumps that are facing away from the chip, the method further includes:

Forming a redistribution layer on one side of the molded packaging layer where the first conductive bumps are exposed, which is the side further away from the chips; the redistribution layer is thus between the first conductive bumps and the third conductive bumps, and the first conductive bumps are connected to the third conductive bumps through the redistribution layer.

In some embodiments, the redistribution/re-wiring layer is a metal film layer and can be prepared by electroplating or deposition processes; the metal material can be at least one of copper, aluminum, silver, gold and titanium. The materials selected for the first conductive bumps, the third conductive bumps and the redistribution layer can be the same or different and are not limited to the materials described herein.

Specifically, a redistribution layer is formed on the surface of one side, that is facing away from the chip, on the molded packaging/molding layer, and the redistribution layer is electrically connected to the first conductive bumps exposed on the surface; then, third conductive bumps are formed on a surface of the redistribution layer, which is facing away from the first conductive bump.

In some embodiments, as shown in FIG. 3, this is another detailed flowchart of S110 in the method of manufacturing a chip package shown in FIG. 1. Referring to FIG. 3, “forming first conductive bumps and an interconnection device on a surface on one side of a first support carrier” includes:

S311, attaching the passive side of the interconnection device to a surface on one side of the first support carrier.

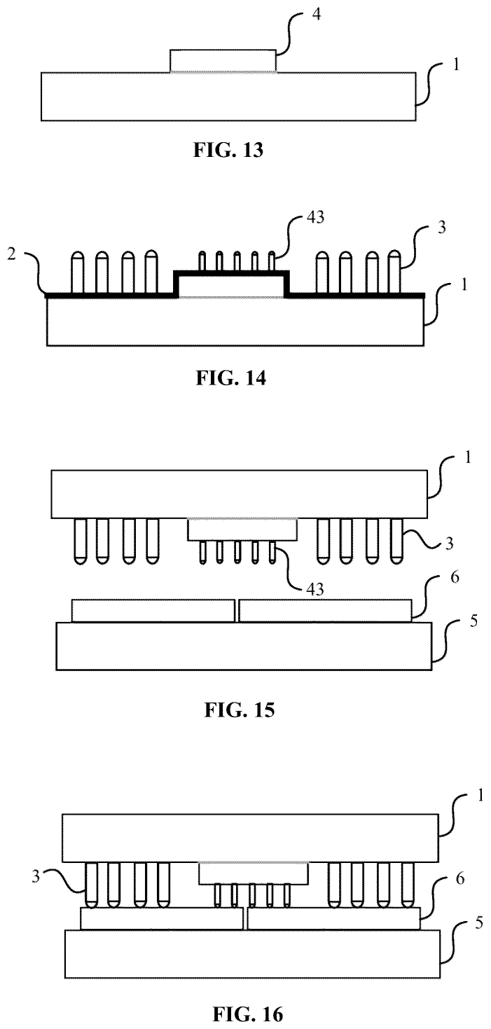

In this embodiment, as shown in FIGS. 13 to 14, the interconnection device 4 is attached to a surface on one side of the first support carrier 1, and afterwards the second conductive bumps 3 and the second conductive bumps 43 are formed.

Illustratively, as shown in FIG. 13, the passive side of the interconnection device 4 is attached to a surface on one side of the first support carrier 1 with adhesive or sticky attachment film.

S312, form a seed layer over the interconnect device and the first support carrier on one side of the first support carrier where the interconnection device is attached. In some embodiments, the seed layer covers a surface of the first support carrier around the interconnection device, an active side of the interconnection device, and a peripheral surface of the interconnection device.

Specifically, in connection with FIG. 14, the seed layer 2 is formed on the surface of the first support carrier 1 around the interconnection device 4, on the active side of the interconnection device 4, and on the peripheral surface between the active side and the passive side of the interconnection device 4.

It should be noted that the peripheral surface of the interconnection device 4 can be provided as a slope surface, i.e., the dimension of the active side is smaller than the dimension of the passive side. Thus, the shape of a cross section of the interconnection device is trapezoidal. This arrangement facilitates the formation of a uniform seed layer on the peripheral surface of the interconnection device 4, reducing the difficulty of operation.

S313, form first conductive bumps on a first part of the seed layer over an area of the first support carrier around the interconnect device on a surface of the seed layer that is facing away from the first support carrier, and form second conductive bumps on a second part of the seed layer on the interconnection device on a surface of the seed layer that is facing away from the interconnection device.

Illustratively, as shown in FIG. 14, the first conductive bumps 3 and the second conductive bumps 43 are formed in holes of a photoresist layer (not shown) using electroplating, deposition, or all processes known to those skilled in the technologies. The photoresist layer is subsequently removed.

In some embodiments, as shown in FIG. 15, before the active side of each chip 6 is connected to the first conductive bumps 3 and the second conductive bumps 43, respectively, the preparation method further includes:

Removing the seed layer.

Illustratively, as shown in FIG. 15, the seed layer is removed using, for example, an etching process, prior to connecting the chip 6 to the first conductive bumps 3 and the second conductive bumps 43.

After removing the seed layer, the following steps are sequentially performed. The active side of each chip 6 is connected to the first conductive bumps 3 and the second conductive bumps 43, respectively (as shown in FIG. 16). A molded packaging layer or molding layer 7 is formed between the first support carrier 1 and the second support carrier 5 (as shown in FIG. 17). The first support carrier and the second support carrier (as shown in FIG. 10) are then removed. The third conductive bumps 8 are formed on exposed bottom surfaces of the first conductive bumps 3 that are facing away from the chips 6 (as shown in FIG. 11). So, the first conductive bumps 3 can be electrically connected to the external device 9 through the third conductive bumps 8 (as shown in FIG. 12).

It should be noted that FIGS. 4-8 show the main steps corresponding to the forming of the first conductive bumps and then attaching the interconnection device on the first support carrier, and FIGS. 13-17 show the main steps corresponding to attaching the interconnection device before forming the first conductive bumps on the first support carrier. The steps after the chips are connected to the first conductive bumps and the second conductive bumps are mostly similar or identical, and reference can be made to the explanation of the corresponding steps above, which are not repeated herein.

On the basis of the foregoing embodiments, the embodiment of the present disclosure further provides a chip package, and the chip package is prepared by using any one of the foregoing preparation methods, which has a corresponding beneficial effect, and is not presented herein to avoid repeated description.

Illustratively, as shown in FIG. 10, the chip package includes: first conductive bumps 3, an interconnection device 4 and at least two chips 6; the interconnection device 4 has opposing active and passive sides, the active side of the interconnection device 4 including second conductive bumps 43; the active side of each chip 6 is connected to the first conductive bumps 3 and the second conductive bumps 43, respectively.

In some embodiments, as shown in FIG. 12, the chip package further includes: a molded packaging layer or molding layer 7; the molded packaging or molding layer 7 embeds the interconnection device, the first conductive bumps 3, the second conductive bumps 43 and the chip 6; the first conductive bumps 3 are exposed at a side of the molding layer 7 that is facing away from the chip 6.

Illustratively, as shown in FIGS. 10-12, the molding layer 7 not only covers the surfaces of the interconnection device 4, the first conductive bumps 3, the second conductive bumps 43, and the chip 6, but also fills the gaps between the interconnection device 4, the first conductive bumps 3, the second conductive bumps 43, and the chip 6.

The first conductive bumps 3 are exposed on a surface of the molding layer 7 that is facing away from the chip 6, thus the first conductive bumps 3 are electrically connected to the third conductive bumps 8.

In some embodiments, as shown in FIG. 12, the chip package further includes: third conductive bumps 8; the third conductive bumps 8 are positioned on one side of the molding layer 7 that is facing away from the chip 6 and is connected to the first conductive bumps 3; the third conductive bumps 3 are used for connecting to an external device 9.

The third conductive bumps 8 can be configured as a column, a block, or a sphere, and the material is an electrically conductive material, including a metal material (such as at least one of copper, aluminum, silver, gold, and titanium) and an electrically conductive nonmetallic material. The number and arrangement of the third conductive bumps are flexibly set according to the external device 9, which is not limited herein.

The external devices 9 include, but are not limited to, a substrate, a printed circuit board, and a processor, which can be a central processing unit or other form of processing unit having data processing capabilities and/or instruction execution capabilities.

In some embodiments, the chip package further includes: a redistribution layer; the redistribution layer is located between the first conductive bumps and the third conductive bumps, and the first conductive bumps are electrically connected to the third conductive bumps through the redistribution layer.

In other embodiments, the chip package further includes all the constituent parts known to the person skilled in the technologies, such as a sealing layer for fixing and sealing the third conductive bumps, or connectors 10 located at the external device 9 that is facing away from the third conductive bumps 8, which is not limited herein.

It should be noted that in this document, relational terms such as “first” and “second” and the like are used solely to distinguish one entity or action from another entity or action without necessarily requiring or implying any actual such relationship or order between such entities or actions. Moreover, the terms “comprises,” “comprising,” or any other variation thereof, are intended to cover a non-exclusive inclusion, such that a process, method, article, or apparatus that comprises a list of elements does not include only those elements but can include other elements not expressly listed or inherent to such process, method, article, or apparatus. Without further limitation, an element defined by the phrase “comprising one . . . ” does not exclude the presence of other like elements in a process, method, article, or apparatus that comprises the element.

The foregoing is merely a specific embodiment of the disclosure to enable one skilled in the technologies to understand or practice the disclosure. Various modifications to these embodiments will be readily apparent to those skilled in the technologies, and the generic principles defined herein can be applied to other embodiments without departing from the spirit or scope of the disclosure. Thus, the present disclosure is not intended to be limited to the embodiments shown and described herein but is to be accorded the widest scope consistent with the principles and novel features disclosed herein.

1. A method of fabricating a chip package, comprises:
providing a first support carrier;
forming first conductive bumps and an interconnection device on a surface on one side of the first support carrier, wherein the interconnection device has opposing active and passive sides, the passive side of the interconnection device being attached to the first support carrier, the active side of the interconnection device having second conductive bumps;
providing at least two chips, each chip of the at least two chips having an active side and an opposing passive side; and
connecting the active side of each chip of the at least two chips to a respective subset of the first conductive bumps and a respective subset of the second conductive bumps.

2. The method of claim 1, wherein forming the first conductive bumps and the interconnection device on the surface on one side of the first support carrier comprises:
forming a seed layer on the surface on the one side of the first support carrier;
forming a photoresist layer with a through hole pattern on a surface on one side of the seed layer that is facing away from the first support carrier, the through hole pattern including through holes penetrating the photoresist layer;
forming the first conductive bumps in respective ones of the through holes; and
removing the photoresist layer; and
attaching the passive side of the interconnection device to a surface on the side of the seed layer that is facing away from the first support carrier.

3. The method of claim 1, wherein forming the first conductive bumps and the interconnection device on the surface on one side of the first support carrier comprises:
attaching the passive side of the interconnection device to the surface on one side of the first support carrier;
forming a seed layer over the interconnect device and the first support carrier, the seed layer having a first portion covering a part of the surface on the one side of the first support carrier around the interconnect device, a second portion covering an active side of the interconnection device, and a third portion between the first portion and the second portion, the third portion covering a peripheral surface of the interconnection device; and
forming the first conductive bumps and the second conductive bumps, wherein the first conductive bumps are formed on a surface of the first portion of the seed layer that is facing away from the first support carrier, and the second conductive bumps are formed on a surface of the second portion of the seed layer that is facing away from the interconnection device.

4. The method of claim 3, wherein forming the first conductive bumps and the second conductive bumps comprises:
forming a photoresist layer over the interconnect device and the first support carrier on one side of the seed layer that is facing away from the first support carrier and the interconnect device, the photoresist layer having a through hole pattern, wherein the through hole pattern includes through holes penetrating the photoresist layer;
forming the first conductive bumps and the second conductive bumps in respective ones of the through holes; and
removing the photoresist layer;

5. The method of claim 3, wherein before the active side of each of the at least two chips is connected to a respective subset of the first conductive bumps and a respective subset of the second conductive bumps, the method further comprising:
removing the seed layer.

6. The method of claim 1, wherein before the active side of each of the at least two chips is connected to a respective subset of the first conductive bumps and a respective subset of the second conductive bumps, the method further comprises:
providing a second support carrier; and
attaching the passive side of each of the at least two chips to a surface on one side of the second support carrier.

7. The method of claim 6, wherein the active sides of the at least two chips are concurrently connected to respective subsets of the first conductive bumps and respective subsets of the second conductive bumps while the at least two chips are attached to the second support carrier.

8. The method of claim 7, further comprising:
forming a molded packaging layer between the first support carrier and the second support carrier; wherein the molded packaging layer embeds the interconnection device, the first conductive bumps, the second conductive bumps, and the at least two chips.

9. The method of claim 8, further comprising:
removing the first support carrier to expose bottom surfaces of the first conductive bumps on one side of the molded package layer;
forming third conductive bumps on respective ones of the bottom surfaces of the first conductive bumps, the third conductive bumps being respectively connected to the first conductive bumps and configured to connect the at least two chips to an external device.

10. The method of manufacturing of claim 8, further comprising:
forming a redistribution layer on the side of the molded package layer where bottom surfaces of the first conductive bumps are exposed; and
forming third conductive bumps on a side of the redistribution layer facing away from the first conductive bumps, wherein the first conductive bumps are connected to the third conductive bumps through the redistribution layer.
